(19) United States
(12) Patent Application Publication
(10) Pub. No.: US 2018/0144807 A1
(43) Pub. Date: May 24, 2018

(54) SEMICONDUCTOR DEVICE

(71) Applicant: Renesas Electronics Corporation, Tokyo (JP)

(72) Inventor: Seiji SAWADA, Tokyo (JP)

(73) Assignee: Renesas Electronics Corporation, Tokyo (JP)

(21) Appl. No.: 15/819,106

(22) Filed: Nov. 21, 2017

(30) Foreign Application Priority Data
Nov. 24, 2016 (JP) 2016-227882

(51) Int. Cl. G11C 16/34; G11C 16/10

(52) U.S. Cl. CPC G11C 16/3459; G11C 16/08; G11C 16/10

(57) ABSTRACT

The present disclosure provides a semiconductor device that can reduce the power consumption. The semiconductor device includes memory cells arranged in a matrix form, and a verify circuit that performs a verify operation to verify whether or not data is written to a memory cell. The verify circuit performs the verify operation when write data is in a first state, and dose not perform the verify operation when the write data is in a second state.

### CROSS-REFERENCE TO RELATED APPLICATIONS

The disclosure of Japanese Patent Application No. 2016-227882 filed on Nov. 24, 2016 including the specification, drawings and abstract is incorporated herein by reference in its entirety.

### BACKGROUND

The present disclosure relates to a semiconductor device, and for example, relates to a semiconductor device such as a microcomputer provided with nonvolatile memory.

Flash memory uses a nonvolatile memory element of MOSFET with a double gate structure having a control gate and a floating gate, as a memory cell. Flash memory is designed to store information by changing the threshold voltage of the MOSFET by changing the amount of charge accumulated in the floating gate.

In this regard, when the data is stored or deleted, a verify operation is generally performed to verify whether the data is normally stored or deleted (Patent Document 1: Japanese Unexamined Patent Application Publication No. 2013-33565).

### SUMMARY

On the other hand, repetition of the verify operation will result in an increase in power consumption.

The present disclosure has been made to solve the above problem, and an object thereof is to provide a semiconductor device capable of reducing the power consumption.

Other objects, advantages and novel features of the disclosure will be set forth in the following detailed description when considered in conjunction with the drawings.

According to an embodiment, a semiconductor device is provided with memory cells arranged in a matrix form, and a verify circuit that performs a verify operation to verify whether or not data is written to a memory cell. The verify circuit performs the verify operation when write data is in a first state. However, the verify circuit does not perform the verify operation when the write data is in a second state.

According to an embodiment, the semiconductor device can reduce the power consumption.

### BRIEF DESCRIPTION OF THE DRAWINGS

FIG. 1 is a block diagram showing the configuration of a semiconductor device based on a first embodiment;

FIGS. 2A, 2B, and 2C are diagrams showing the configuration of a memory cell MC based on the first embodiment;

FIG. 3 is a diagram showing a specific configuration of a system control circuit 4, as well as write control circuit and verify circuit 5 based on the first embodiment;

FIG. 4 is a diagram showing write data WD based on the first embodiment;

FIG. 5 is a diagram showing the configuration of a verify unit VU based on the first embodiment;

FIG. 6 is a diagram showing a circuit configuration of a determination circuit 7 based on the first embodiment;

FIGS. 7A and 7B are diagrams showing the operation waveform of a verify operation when the data is written to the memory cell MC based on the first embodiment;

FIG. 8 is a diagram showing the operation waveform of the verify operation when data writing of data “0” is performed based on the first embodiment;

FIG. 9 is a diagram showing a partial configuration of the verify unit, which is a comparative example;

FIG. 10 is a flow chart illustrating the verify operation of each verify unit VU based on the first embodiment;

FIG. 11 is a diagram showing the configuration of a verify unit VU# based on a second embodiment;

FIGS. 12A and 12B are diagrams showing the operation waveform of the verify operation when the data is written to the memory cell MC based on the second embodiment;

FIG. 13 is a diagram showing the operation waveform of the verify operation when data writing of data “0” is performed based on the second embodiment;

FIG. 14 is a diagram showing the configuration of a verify unit VU#A based on a third embodiment;

FIGS. 15A and 15B are diagrams showing the operation waveform of the verify operation when the data is written to the memory cell MC based on the third embodiment; and

FIG. 16 is a diagram showing the operation waveform of the verify operation when data writing of data “0” is performed based on the third embodiment.

### DETAILED DESCRIPTION

Preferred embodiments of the present disclosure will be described below in detail with reference to the accompanying drawings. It is to be noted that like or corresponding parts are designated by like reference numerals throughout the accompanying drawings.

### First Embodiment

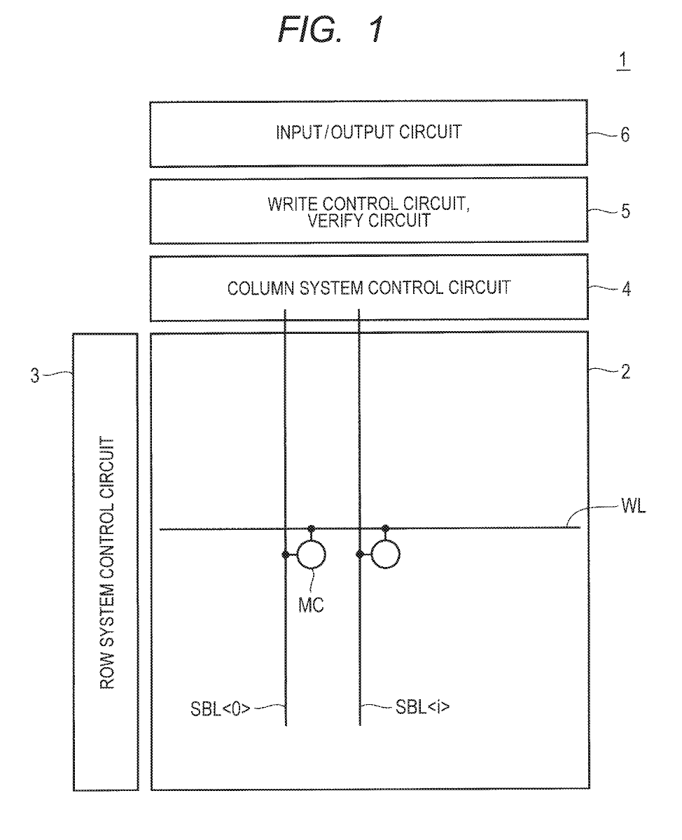

FIG. 1 is a block diagram showing the configuration of a semiconductor device based on a first embodiment.

As shown in FIG. 1, a nonvolatile semiconductor memory device is described in the present embodiment as a semiconductor device.

A semiconductor device 1 includes a memory array 2, a row system control circuit 3, a column system control circuit 4, write control circuit and verify circuit 5, and an input/output circuit 6.

The memory array 2 includes a plurality of memory cells MC arranged in a matrix form.

The memory array 2 includes a plurality of word lines WL provided corresponding to each of the memory cell rows, and a plurality of bit lines provided corresponding to each of the memory cell columns.

In the present embodiment, a plurality of sub-bit lines SBL are provided corresponding to each of the memory cell columns. Note that the sub-bit line SBL is coupled to a main bit line through a selector, which will be described in detail below.

In the present embodiment, a word line WL as well as sub-bit lines SBL <0> and SBL <i> are shown as an example. Hereinafter, the sub-bit lines SBL <0> and SBL <i> are also generically referred to as sub-bit lines SBL. Note that although not shown, other lines such as, for example, a source line and a line for supplying substrate voltage are also provided.

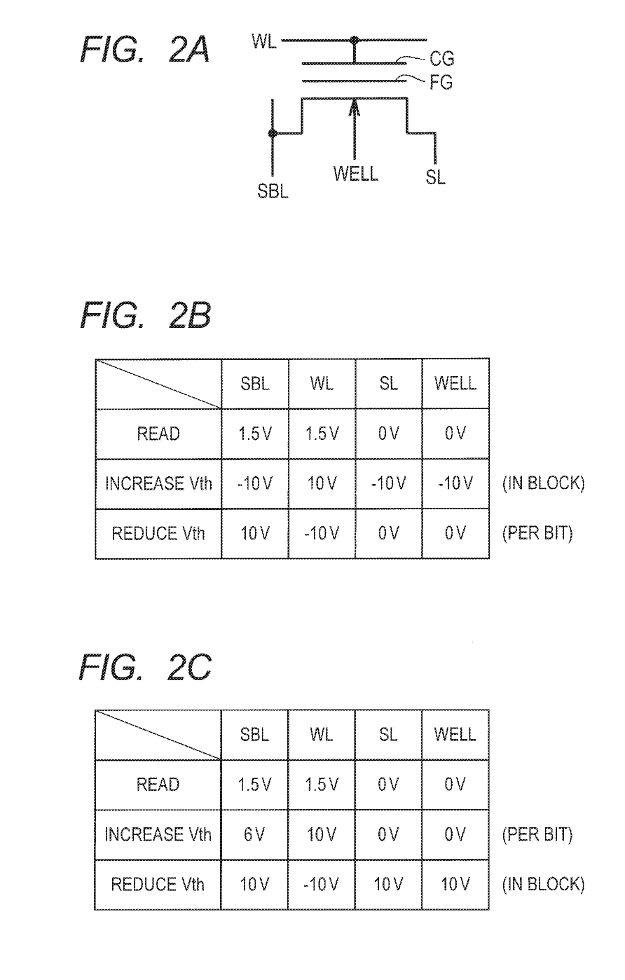

FIGS. 2A, 2B, and 2C are diagrams showing the configuration of the memory cell MC based on the first embodiment.

A stacked gate type flash memory element shown in FIG. 2A is configured such that a floating gate FG and a control gate CG are stacked over a channel formation region between a source region and a drain region through a gate insulating film. The control gate CG is coupled to the word line WL. The drain region is coupled to the sub-bit line SBL. Then, the source region is coupled to a source line SL.

FIGS. 2B and 2C show an example of voltage setting of the sub-bit line SBL, the word line WL, the source line SL, and the well region (WELL) in reading and writing/deletion of the stacked gate type flash memory element.

FIG. 2B shows an example of voltage setting when a threshold voltage Vth is increased by an FN tunnel writing method and when the threshold voltage Vth is reduced by electron emission to the sub-bit line SBL.

FIG. 2C shows an example of voltage setting when the threshold Vth is increased by a hot-carrier writing method and when the threshold voltage Vth is reduced by electron emission to the well region.

Note that the control gate CG is also referred to as control electrode, the impurity region coupled to the sub-bit line SBL is also referred to as first main electrode, and the impurity region coupled to the source line SL is also referred to as second main electrode.

For example, in reading, SBL is set to 1.5 V, WL is set to 1.5 V, SL is set to 0 V, and WELL is set to 0 V. When the threshold voltage Vth of the memory cell is low, the resistance of the memory cell is reduced (ON state). When the threshold voltage Vth of the memory cell is high, the resistance of the memory cell is increased (OFF state).

In order to increase the threshold voltage Vth of the memory cell, for example, SBL is to set to −10 V, WL is set to 10 V, SL is set to −10 V, and WELL is set to −10 V.

On the other hand, in order to reduce the threshold voltage Vth of the memory cell, for example, SBL is set to 10 V, WL is set to −10 V, SL is set to 0 V, and WELL is set to 0 V.

For example, it is possible to store the case where the threshold voltage Vth of the memory cell is high as data “1” or “0”, and to store the case where the threshold voltage Vth of the memory cell is low as data “0” or “1”. In the present embodiment, it is assumed that the case where the threshold voltage Vth is high is data “1” and the case where the threshold voltage Vth is low is data “0”.

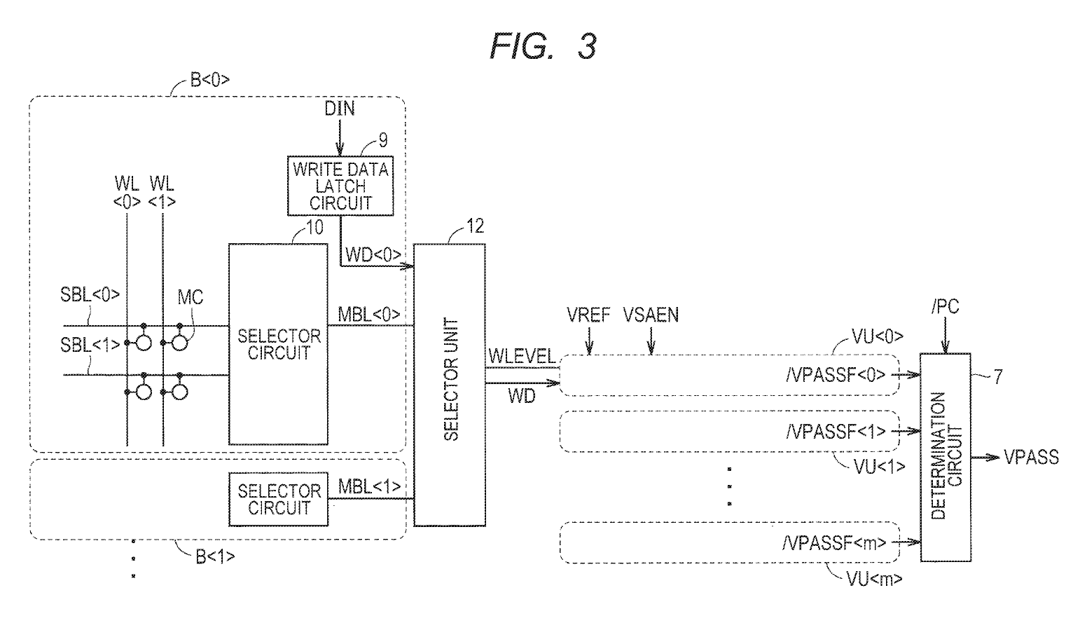

FIG. 3 is a diagram showing a specific configuration of the column system control circuit 4 and the write control circuit and verify circuit 5 based on the first embodiment.

As shown in FIG. 3, here the memory array 2 is divided into a plurality of blocks B. In the present embodiment, the memory array 2 is configured to be able to read and write data in the unit of block B. The column system control circuit 4 includes a selector unit 12 and a main bit line MBL. In the present embodiment, data can be written and read in parallel on m+1 bits. In the present embodiment, although not shown, a deletion circuit in which data can be deleted in block is assumed to be provided. Further, when data rewriting (update) is performed on a memory cell MC with the same address, the data is once deleted by the deletion circuit and then data writing is permitted. Thus, data writing is performed in a state in which the threshold voltage Vth is low with data “0”.

A selector 10 and a write data latch circuit 9 are provided in each block B. The write data latch circuit 9 receives input of data DIN<0>, DIN<1>, and so on, and latches the input data.

A plurality of sub-bit lines SBL are coupled to the selector 10.

The selector 10 selects one of the coupled sub-bit lines SBL and couples the selected sub-bit line SBL to the main bit line MBL according to an address signal.

The selector unit 12 is coupled to a plurality of main bit lines MBL. The selector unit 12 selects one of the main bit lines MBL according to the address signal. In the present embodiment, main bit lines MBL<0> and MBL<1> are shown as an example.

The write control circuit and verify circuit 5 includes a plurality of verify units VU. As an example, verify units VU<0> to VU<m> are provided in this embodiment.

Each block B corresponds to each main bit line MBL, and the verify unit VU is provided in each unit of blocks B.

Further, the write control circuit and verify circuit 5 includes the determination circuit 7.

The verify unit VU receives input of write data WD as well as input of verify data read from the memory cell MC. The verify unit VU performs a determination process to determine whether or not the write data WD is properly written to the memory cell MC for each bit. Then, the verify unit VU outputs signal /VPASSF based on the determination result.

Each of the verify units VU outputs signal /VPASSF based on the determination result to the determination circuit 7.

In the present embodiment, the determination circuit 7 receives the signal of each of the m+1 verify units VU, and outputs determination signal VPASS. The determination circuit 7 is activated in response to activation signal /PC. As an example, when the determination signal VPASS is “H” level, it is determined that the data writing is normally performed. On the other hand, when the determination signal VPASS is “L” level, it is determined that the data writing is abnormal, and data writing is performed again.

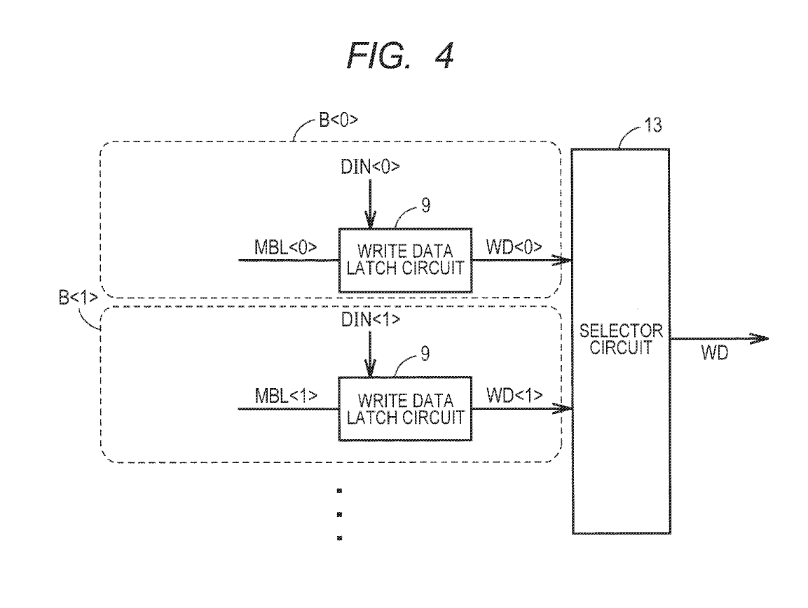

FIG. 4 is a diagram showing the write data WD based on the first embodiment.

Referring to FIG. 4, the selector circuit 13 receives input of write data WD<0> and WD<1> from the write data latch circuit 9 that is provided in each block B. Then, the selector circuit 13 selects either WD<0> or WD<1> and outputs as write data WD. Note that the selector circuit 13 may be included in the selector unit 12.

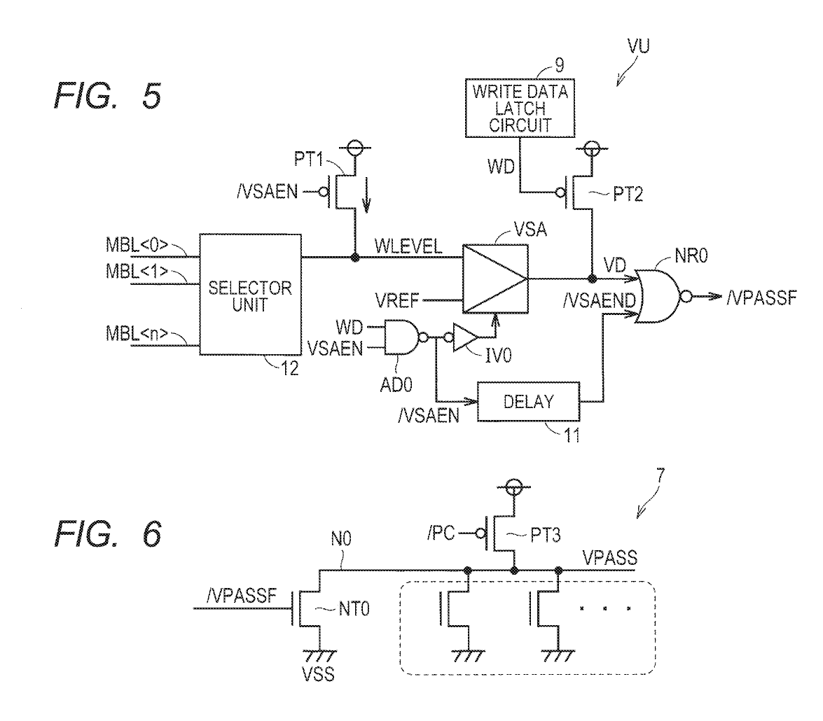

FIG. 5 is a diagram showing the configuration of the verify unit VU based on the first embodiment.

As shown in FIG. 5, the verify unit VU includes a verify sense amplifier VSA, transistors PT1 and PT2, an inverter IV0, a NAND circuit AD0, a delay 11, and a NOR circuit NR0. As an example, the transistors PT1 and PT2 are P-channel MOS transistors.

The transistor PT1 is provided between a data line and a power supply voltage VDD. The data line is provided between the selector unit 12 and the verify sense amplifier VSA. The gate of the transistor PT1 receives an input of control signal /VSAEN. The transistor PT1 is conductive in response to an input of control signal /VSAEN (“L” level). In accordance with this, the data line is charged to the power supply voltage VDD.

The selector 12 selects one of the main bit lines MBL and electrically couples to the data line.

In accordance with this, the current corresponding to the data of the memory cell MC flows through the main bit line MBL.

when the data is “1”, the memory cell MC is set to a state in which the threshold voltage is high, so that voltage WLEVEL of the data line is set to a value equal to or higher than reference voltage VREF.

On the other hand, when the data is “0”, the memory cell MC is set to a state in which the threshold voltage is low, so that the voltage WLEVEL of the data line is lower than the reference voltage VREF.

The verify sense amplifier VSA is activated in response to the activation signal.

The verify sense amplifier VSA compares the data line voltage WLEVEL with the reference voltage VREF, and outputs verify data VD. When the data line voltage WLEVEL is equal to or higher than the reference voltage VREF, the verify sense amplifier VAS outputs verify data VD (“H” level).

When the data line voltage WLEVEL is lower than the reference voltage VREF, the verify sense amplifier VAS outputs verify data VD (“L” level).

The NAND circuit AD0 outputs the result of the NAND operation between the write data WD and the control signal VSAEN (signal /VSAEN). The inverter IV0 outputs an inverted signal of the output of the NAND circuit AD0 as the activation signal to activate the verify sense amplifier VSA.

The delay 11 delays the output (signal /VASEN) of the NAND circuit AD0 by a predetermined time and outputs control signal /VSAEND.

The NOR circuit NR0 outputs the result of the NOR operation between the verify data VD, which is output from the verify sense amplifier VSA, and the control signal /VSAEND, as signal /VPASSF.

The transistor PT2 is provided between the output node of the verify sense amplifier VSA and the power supply voltage VDD. The gate of the transistor PT2 receives an input of write data WD from the write data latch circuit 9.

When the write data WD is “0” (“L” level), the transistor PT2 is conductive. Thus, the output node of the verify sense amplifier VSA is forcibly set to “H” level. In accordance with this, the verify unit VU is set to an invalid state based on the write data WD.

More specifically, when the write data WD is “0” (“L” level), the output node of the verify sense amplifier VSA is forcibly set to “H” level. Thus, the output signal /VPASSF of the NOR circuit NR0 is set to “L” level, regardless of the logic level of the control signal /VSAEND. Thus, in this case, it is determined that the writing to the memory cell MC is completed.

Further, when the write data WD is “0” (“L” level), the NAND circuit AD0 is set to “H” level. Thus, the activation signal through the inverter IV0 is set to “L” level. As a result, the verify sense amplifier VSA goes into an inactive state.

On the other hand, when the write data WD is “1” (“H” level), the verify unit VU performs a normal operation. More specifically, when the write data WD is “1” (“H” level), the transistor PT2 is in a non-conductive state.

Further, when the write data WD is “1” (“H” level), the NAND circuit AD0 outputs a signal of “L” level, which is the result of the NAND operation, in response to an input of control signal VSAEN (“H” level). Then, an activation signal (“H” level) is output through the inverter IV0. In accordance with this, the verify sense amplifier VSA goes into an active state.

Thus, the verify sense amplifier VSA outputs verify data VD based on the data written in the memory cell MC. Then, the NOR circuit NR0 outputs the signal /VPASSF based on the result of the NOR operation between the verify data VD and the signal /VSAEND. When the write data WD is “1” and the same data is written in the memory cell MC, the signal /VPASSF is changed to “L” level. In this case, it is determined that the writing to the particular memory cell MC is completed.

On the other hand, when the data writing to the memory cell MC is in process and the voltage level does not reach the desired threshold voltage level (when the write data WD is “1” and different data is still written in the memory cell MC), the signal /VPASSF is changed to “H” level. In this case, it is determined that the writing to the particular memory cell MC is not completed.

FIG. 6 is a diagram showing the circuit configuration of the determination circuit 7 based on the first embodiment.

As shown in FIG. 6, the determination circuit 7 includes a plurality of transistors.

In the present embodiment, it is shown that transistors PT3 and NT0 are provided. As an example, the transistor PT3 is a P-channel MOS transistor. As an example, the transistor NT0 is an N-channel MOS transistor. The transistor PT3 is provided between the power supply voltage VDD and the node N0. The gate of the transistor PT3 receives an input of activation signal /PC. The transistor NT0 is provided between the node NO and a ground voltage VSS. The gate of the transistor NT0 receives an input of signal /VPASSF. The transistor PT3 is conductive in response to an input of activation signal /PC (“L” level). In accordance with this, the node N0 is charged to the power supply voltage. Next, the transistor NT0 is conductive in response to an input of signal VPASSF (“H” level). The transistor NT0 maintains the non-conductive state upon input of signal /VPASSF (“L” level).

In the present embodiment, the signal /VPASSF is output from each of the verify units VU. At this time, when all signals /VPASSF output from the respective verify units VU are “L” level, the node N0 is kept charged to the power supply voltage VDD. As a result, the signal VPASS is changed to “H” level.

On the other hand, when at least one or more of the signals /VPASSF output from the respective verify units VU is “H” level, the transistor NT0 is conductive. For this reason, the power supply voltage VDD charged in the node N0 is drawn to the side of the ground voltage VSS. As a result, the signal VPASS is changed to “L” level.

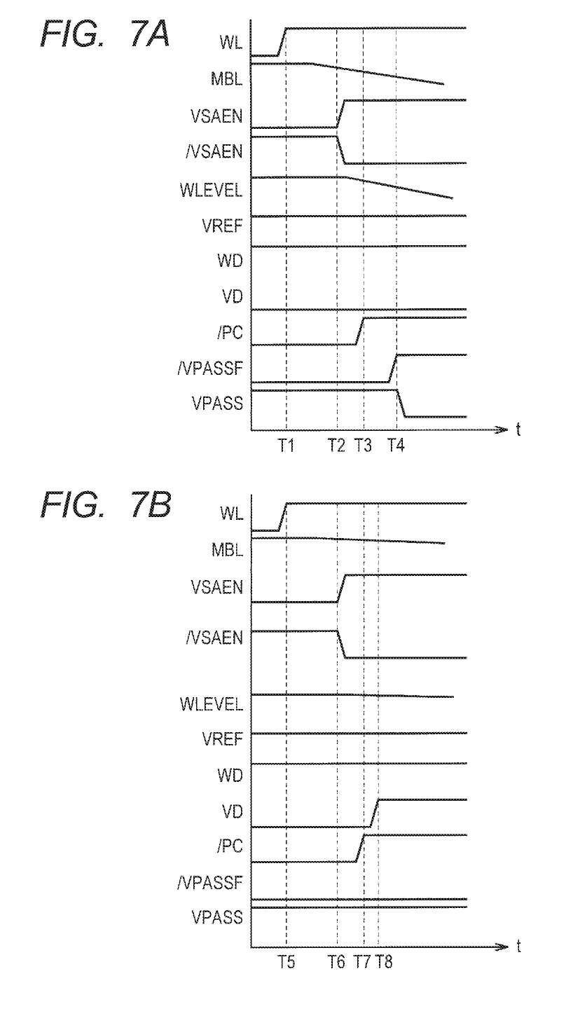

FIGS. 7A and 7B are diagrams showing the operation waveform of verify operation when data writing to the memory cell MC is performed based on the first embodiment.

FIG. 7A shows the operation waveform when the data writing of data “1” is not completed.

At time T1, the word line WL is selected, and the memory cell MC and the sub-bit line SBL are coupled to each other. Further, the sub-bit line SBL and the main bit line MBL are coupled to each other according to the selector 10. Then, the main bit line MBL and the data line are electrically coupled to each other according to the selector unit 12.

Further, at time T1, the activation signal /PC is set to “L” level. In this way, the node N0 is charged to the power supply voltage VDD.

Next, at time T2, the control signal VSAEN is set to “H” level. In accordance with this, the control signal /VSAEN is set to “L” level. Then, the transistor PT1 is conductive and the data line is charged to the power supply voltage VDD.

On the other hand, the threshold voltage Vth of the memory cell MC is in a low state, so that the current flows through the memory cell MC. Thus, the potential of the main bit line MBL is reduced. Further, the voltage WLEVEL of the data line coupled to the main bit line MBL is also reduced.

Because the data writing is performed on data “1”, the write data WD is kept at “H” level.

In accordance with this, the verify sense amplifier VSA outputs verify data VD of “L” level.

Then, at time T3, the activation signal /PC is set to “H” level. In accordance with this, the determination circuit 7 is activated. The charging of the node N0 to the power supply voltage VDD is completed.

On the other hand, the verify data VD is “L” level, so that the signal /VPASSF is set to “H” level at time T4. Thus, the transistor NT3 of the determination circuit 7 is conductive and the determination signal VPASS is set to “L” level.

Based on this result, rewriting is performed.

Next, FIG. 7B shows the operation waveform when the data writing of data “1” is completed.

At time T5, the word line WL is selected and the memory cell MC and the sub-bit line SBL are coupled to each other. Further, the sub-bit line SBL and the main bit line MBL are coupled to each other according to the selector 10. Further, the main bit line MBL and the data line are electrically coupled to each other according to the selector unit 12.

Further, at time T5, the activation signal /PC is set to “L” level. In this way, the node N0 is charged to the power supply voltage VDD.

Next, at time T6, the control signal VASEN is set to “H” level. In accordance with this, the control signal /VSAEN is set to “L” level. Then, the transistor PT1 is conductive and the data line is charged to the power supply voltage.

On the other hand, the threshold voltage Vth of the memory cell MC is in a high state, so that the current is not likely to flow through the memory cell MC. At this time, the voltage WLEVEL of the data line coupled to the main bit line MBL is kept in the high state.

Because the data writing is performed on data “1”, the write data WD is kept at “H” level.

In accordance with this, the verify sense amplifier VAS outputs verify data VD of “H” level.

Then, at time T7, the activation signal /PC is set to “H” level. In accordance with this, the determination circuit 7 is activated. The charging of the node N0 to the power supply voltage VDD is completed.

On the other hand, the verify data VD is “H” level, so that the signal /VPASSF is set to “L” level at time T8. Thus, the transistor NT3 of the determination circuit 7 is in a non-conductive state, so that the determination signal VPASS is set to “H” level.

Based on this result, it is possible to determine that the writing is normally performed.

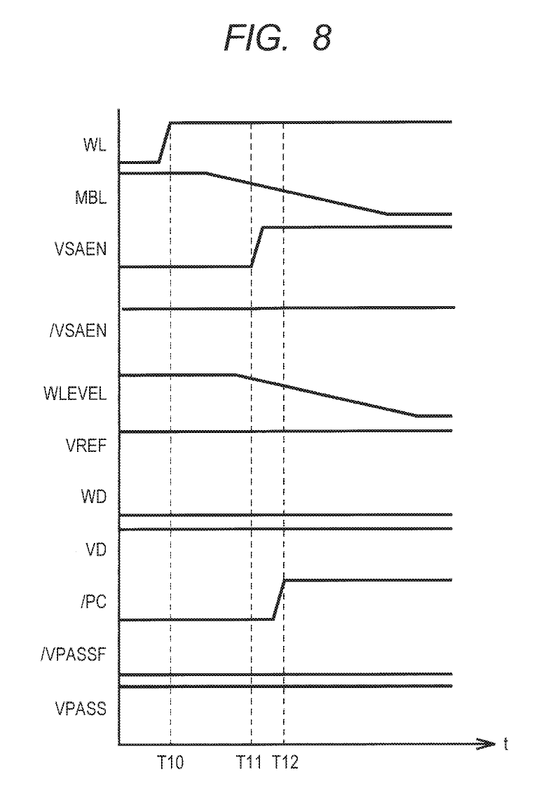

FIG. 8 is a diagram showing the operation waveform of the verify operation for data writing of data “0” based on the first embodiment.

As shown in FIG. 8, at time T10, the word line WL is selected, and the memory cell MC and the sub-bit line SBL are coupled to each other. Further, the sub-bit line SBL and the main bit line BML are coupled to each other according to the selector 10. Further, the main bit line BML and the data line are electrically coupled to each other according to the selector unit 12.

Further, at time T10, the activation signal /PC is set to “L” level. In this way, the node N0 is charged to the power supply voltage VDD.

Next, at time T11, the control signal VSAEN is set to “H” level.

Because the data writing is performed on data “0”, the write data WD is set to “L” level.

Thus, the control signal /VSAEN is kept at “H” level.

In accordance with this, the verify sense amplifier VSA goes into an inactive state and does not operate.

Further, because the transistor PT2 is conductive, verify data VD of “H” level is output. Note that the transistor PT1 is not conductive.

Then, at time T12, the activation signal /PC is set to “H” level. In accordance with this, the determination circuit 7 is activated. The charging of the node N0 to the power supply voltage VDD is completed.

On the other hand, the verify data VD is “H” level, so that the signal /VPASSF is kept at “L” level. Thus, the determination circuit 7 is in a non-conductive state, so that the determination signal VPASS is kept at “H” level.

Therefore, based on this result, it is possible to determine that the writing is normally performed.

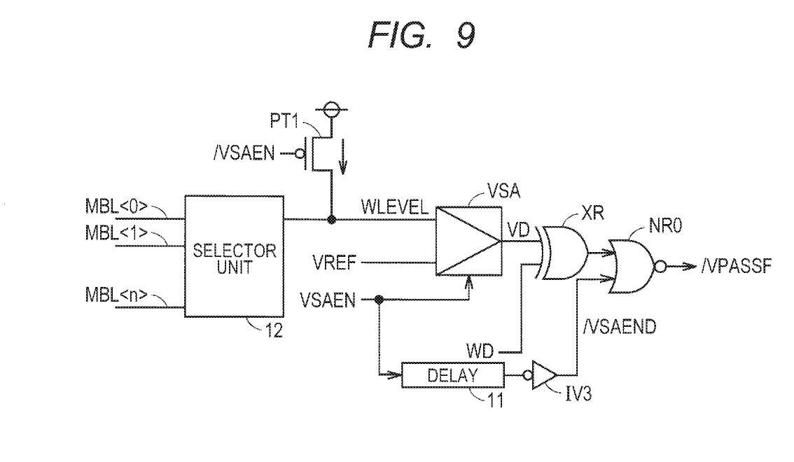

FIG. 9 is a diagram showing a partial configuration of the verify unit, which is a comparative example.

As shown in FIG. 9, compared to the configuration shown in FIG. 5, the verify unit of the comparative example has a configuration in which the control signal VSAEN is directly input to the verify sense amplifier VAS.

Further, the verify unit is also provided with an XOR circuit XR. The XOR circuit XR outputs the result of the XOR operation between the verify data VD, which is the output of the verify sense amplifier VSA, and the write data WD.

The delay 11 receives an input of control signal VSAEN and delays the control signal VSAEN. An inverter IV3 is provided in the subsequent stage of the delay 11. The inverter IV3 outputs the inverted control signal /VSAEND to the NOR circuit NR0.

The NOR circuit NR0 outputs the result of the NOR operation between the output of the XOR circuit XR and the control signal /VSAEND, as signal /VPASSF.

The verify sense amplifier VSA in this configuration is all activated independent of the word data WD, and outputs verify data VD.

On the other hand, in the configuration of this application, the verify sense amplifier VSA is an inactive state when data writing is performed on data “0”, so that it is possible to reduce the power consumption for the verify operation. In addition, the determination signal VPASS of the determination circuit 7 is also set to “H” level, so that rewriting (verify writing) does not take place. As a result, the power consumption can be reduced.

In this regard, it is possible in the present embodiment to write data in parallel on m+1 bits. For example, with respect to the data column included in m+1 bits, a normal verify operation is performed on the verify unit VU corresponding to the block B for the data writing of data “1”. On the other hand, the verify operation is not performed on the verify unit VU corresponding to the block B for the data writing of data “0”. Thus, it is possible to reduce the power consumption of the verify unit VU in which the verify operation is not performed. As a result, it is possible to reduce the power consumption for the verify operation as a whole.

Also, with respect to the block B of data “0”, the verify operation of the rewriting process based on the verify process is not performed, so that it is possible to reduce the power consumption for the verify operation.

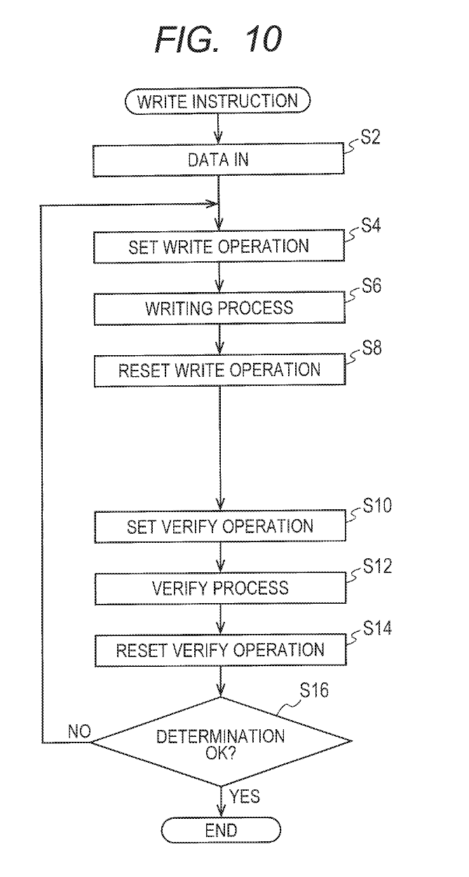

FIG. 10 is a flow chart illustrating the verify operation of each verify unit VU based on the first embodiment.

As shown in FIG. 10, the verify unit VU determines whether or not the data is input (Step S2). The write data latch circuit 9 determines whether or not data DIN is input.

In Step S2, when it is determined that data is input (YES in Step S2), the verify unit VU sets a write operation (Step S4). When it is determined that data DIN is input, the write data latch circuit 9 latches the data DIN and outputs write data WD to the write circuit 8. The write circuit 8 sets a write operation according to the write data WD. More specifically, the write circuit 8 sets various voltage levels to perform the data writing.

Next, the verify unit VU performs the write operation based on the write data WD (Step S6). The write circuit 8 performs the writing process based on the write data WD on a specified memory cell MC.

Next, the verify unit VU resets the write operation (Step 8). The write circuit 8 resets the write operation after the execution of the writing process. More specifically, the write circuit 8 returns the various voltage levels to their initial state.

Next, the verify unit VU determines whether or not the write data is “1” (Step S9).

In Step S9, when the write data is “1”, the process proceeds to Step S10 to set a normal verify operation (Step S10). The verify unit VU sets various voltage levels to perform the verify operation. Further, the verify unit VU activates the verify sense amplifier VSA.

Next, the verify unit VU performs the verify process (Step S12). The verify unit VU outputs verify data VD from the verify sense amplifier VSA. Then, the verify unit VU outputs signal /VPASSF to the determination circuit 7.

Next, the verify unit VU resets the verify operation (Step S14). Then, the verify unit VU returns the various control signals and voltages for performing the verify operation, to their initial state.

On the other hand, when the write data is not “1”, namely, “0”, the process skips Steps S1 to S14.

Next, the verify unit VU determines whether the determination is OK or not (Step S16). In other words, the verify unit VU determines whether or not the signal /VPASSF is “L” level.

When the signal /VPASSF is at “L” level, it is determined that the writing to the particular memory cell MC is completed.

On the other hand, when the signal /VPASSF is “H” level, the determination is determined to be NG. In other words, the signal VPASS is set to “L” level. Thus, the process returns to Step S4 to write the data again.

By this process, it is possible to reduce the power consumption because the operation is not performed in all verify units VU, in other words, the verify unit VU does not perform the verify operation on data “0”.

### Second Embodiment

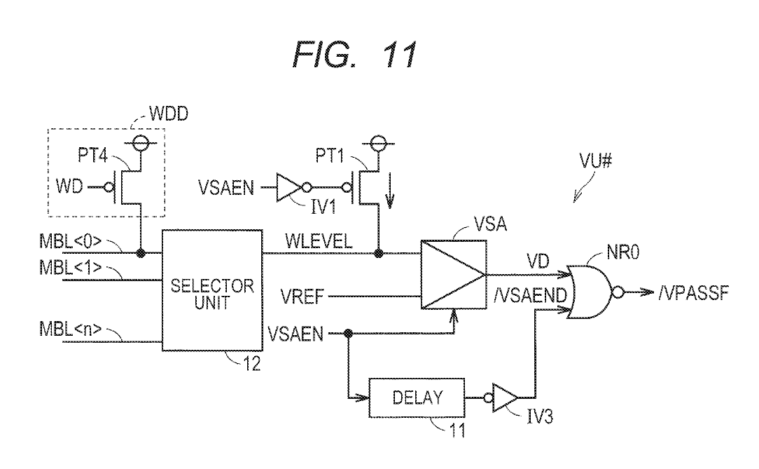

FIG. 11 is a diagram showing the configuration of a verify unit VU# based on a second embodiment.

As shown in FIG. 11, the verify unit VU# includes the verify sense amplifier VSA, transistors PT1 and PT4, inverters IV1 and IV3, the delay 11, and the NOR circuit NR0. As an example, the transistors PT1 and PT4 are P-channel MOS transistors.

The transistor PT1 is provided between the data line and the power supply voltage VDD. The gate of the transistor PT1 receives an input of control signal VSAEN through the inverter IV1. The transistor PT1 is conductive in response to an input of control signal VSAEN (“H” level). In accordance with this, the data line is charged to the power supply voltage VDD.

The selector 12 selects the main bit line MBL in response to an address signal and electrically couples to the data line.

In accordance with this, the current corresponding to the data of the memory cell MC flows through the main bit line MBL.

When the data is “1”, the threshold voltage of the memory cell MC is set to a high state, so that the voltage WLEVEL of the data line is higher than the reference voltage VREF. When the voltage WLEVEL is equal to or higher than the reference voltage VREF, the memory cell MC outputs verify data VD (“H” level).

On the other hand, when the data is “0”, the threshold voltage of the memory cell MC is set to a low state, so that the voltage WLEVEL of the data line is lower than the reference voltage VREF. When the voltage WLEVEL is lower than the reference voltage VREF, the memory cell MC outputs verify data VD (“L” level).

The delay 11 delays the control signal VSAEN by a predetermined time. The inverter IV3 outputs signal VSAEND, which is obtained by inverting the signal output from the delay 11, to the NOR circuit NR0.

The NOR circuit NR0 outputs the result of the NOR operation between the verify data VD, which is output from the verify sense amplifier VSA, and the signal /VSAEND as signal /VPASSF.

In the second embodiment, a pull-up circuit WDD is provided in each main bit line MBL. As an example, FIG. 11 shows the case in which the pull-up circuit WDD is provided in the main bit line MBL<0>. The pull-up circuit WDD is also provided in other main bit lines.

The pull-up circuit WDD includes the transistor PT4. The transistor TP4 is provided between the corresponding bit line BL and the power supply voltage VDD. The gate of the transistor PT4 receives an input of write data WD. The transistor TP4 is conductive in response to the input of write data WD (“L” level). In accordance with this, the bit line is coupled to the power supply voltage VDD.

Thus, when the write data WD of the memory cell MC corresponding to the main bit line MBL is “0” (“L” level), the transistor PT4 is conductive. Thus, the voltage of the main bit line MBL is set to “H” level, and the voltage WLEVEL of the data line coupled to the main bit lint MBL is also set to “H” level.

Therefore, when comparing the data line voltage WLEVEL and the reference voltage VREF, the verify sense amplifier VSA outputs verify data VD of “H” level as the comparison result.

In accordance with this, the output signal /VPASSF from the NOR circuit NR0 is set to “L” level regardless of the logic level of the signal /VSAEND.

On the other hand, when the write data WD is “1” (“H” level), the transistor PT4 goes into a non-conductive state. Thus, the main bit line MBL is set to a voltage level corresponding to the data of the memory cell MC.

When the write data WD is “1” (“H” level), the verify unit VU performs the normal operation. Thus, the verify sense amplifier VAS outputs verify data VD based on the data written in the memory cell MC. Then, the NOR circuit NR0 outputs signal /VPASSF based on the result of the NOR operation between the verify data VD and the signal /VSAEND. When the write data WD is “1” (“H” level) and the same data (“H” level) is written in the memory cell MC, the signal /VPASSF is changed to “L” level. In this case, it is determined that the writing to the particular memory cell MC is completed.

On the other hand, when the write data is “1” (“H” level) and different data (“L” level) is written in the memory cell MC, the signal /VPASSF is changed to “H” level. In this case, it is determined that the writing to the particular memory cell MC is not completed.

The determination circuit 7 is the same as described with reference to FIG. 5, so that a detailed description thereof will not be repeated.

In the present embodiment, the signal /VPASSF is output from each of the verify units VU. At this time, when the signal /VPASSF is “L” level, the node N0 of the determination circuit 7 is kept charged to the power supply voltage VDD. As a result, the signal VPASS is changed to “H” level.

On the other hand, when at least one or more of the signals /VPASSF is “H” level, the transistor NT0 of the determination circuit 7 is conductive. Thus, the power supply voltage VDD charged in the node N0 is drawn to the side of the ground voltage VSS. As a result, the signal VPASS is changed to “L” level.

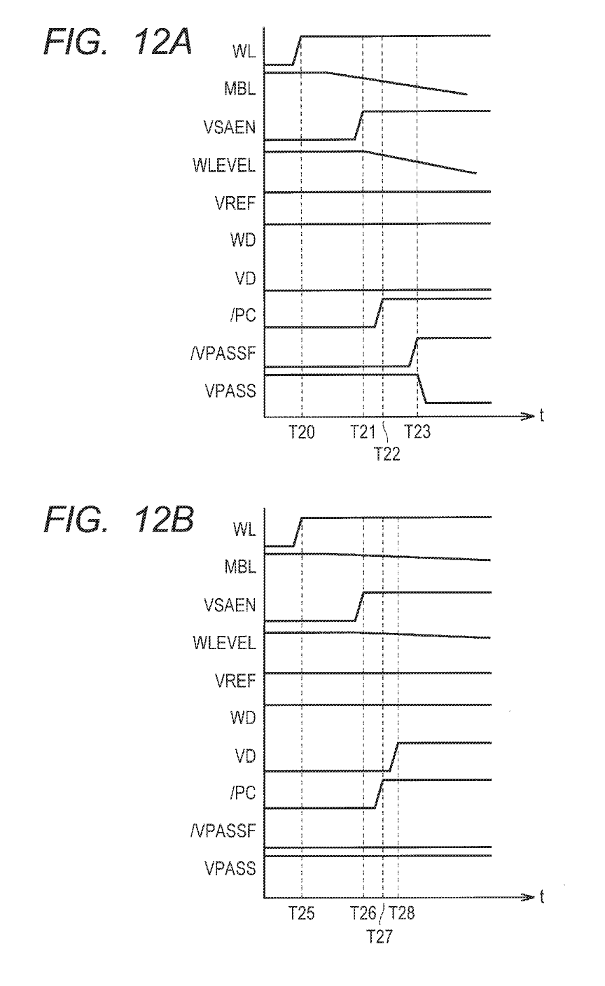

FIGS. 12A and 12B are diagrams showing the operation waveform of the verify operation when the data is written to the memory cell MC based on the second embodiment.

FIG. 12A shows the operation waveform when the data wiring of data “1” is not completed.

At time T20, the word line WL is selected and the memory cell MC and the bit line BL are coupled to each other. Further, the bit line BL and the data line are electrically coupled to each other according to the selector unit 12. Further, at time T20, the activation signal /PC is set to “L” level. In this way, the node N0 is charged to the power supply voltage VDD.

Next, at time T21, the control signal VSAEN is set to “H” level. In accordance with this, the transistor PT1 is conductive, and the data line is charged to the power supply voltage VDD.

On the other hand, the threshold voltage Vth of the memory cell MC is in a low state, so that the current flows through the memory cell MC. Thus, the potential of the bit line BL is reduced. In addition, the level of the data line coupled to the bit line BL is also reduced.

Because the data wiring is performed on data “1”, the write data WD is kept at “H” level. Thus, the transistor PT4 is in a non-conductive state.

The verify sense amplifier VSA is activated in response to the control signal VSAEN, and outputs verify data VD of “L” level.

Then, at time T22, the activation signal /PC is set to “H” level. In accordance with this, the determination circuit 7 is activated. The charging of the node N0 to the power supply voltage VDD is completed.

On the other hand, the verify data VD is “L” level, so that the signal /VPASSF is set to “H” level at time T23. In this way, the transistor NT3 of the determination circuit 7 is conductive and the determination signal VPASS is set to “L” level.

Based on this result, rewriting is performed.

Next, FIG. 12B shows the operation waveform when the data writing of data “1” is completed.

At time T25, the word line WL is selected and the memory cell MC and the bit line BL are coupled to each other. Further, the bit line BL and the data line are electrically coupled to each other according to the selector unit 12. Further, at time T25, the activation signal /PC is set to “L” level. In this way, the node N0 is charged to the power supply voltage VDD.

Next, at time T26, the control signal VSAEN is set to “H” level. In accordance with this, the transistor PT1 is conductive and the data line is charged to the power supply voltage.

On the other hand, the threshold voltage Vth of the memory cell MC is in a high state, so that the current is not likely to flow through the memory cell MC. Thus, the potential of the bit line BL is kept high. Further, the level of the voltage WLEVEL of the data line coupled to the bit line BL is also kept high.

Because the data writing is performed on data “1”, the write data WD is kept at “H” level. Thus, the transistor PT4 is in a non-conductive state.

The verify sense amplifier VSA is activated in response to the control signal VSAEN, and outputs verify data VD of “H” level.

Then, at time T27, the activation signal /PC is set to “L” level. In accordance with this, the determination circuit 7 is activated. The charging of the node N0 to the power supply voltage VDD is completed.

On the other hand, the verify data VD is “H” level, so that the signal /VPASSF is set to “L” level at time T28. Thus, the transistor NT3 of the determination circuit 7 is non conductive, and the determination signal VPASS is set to “H” level.

Based on this result, it is possible to determine that the writing is normally performed.

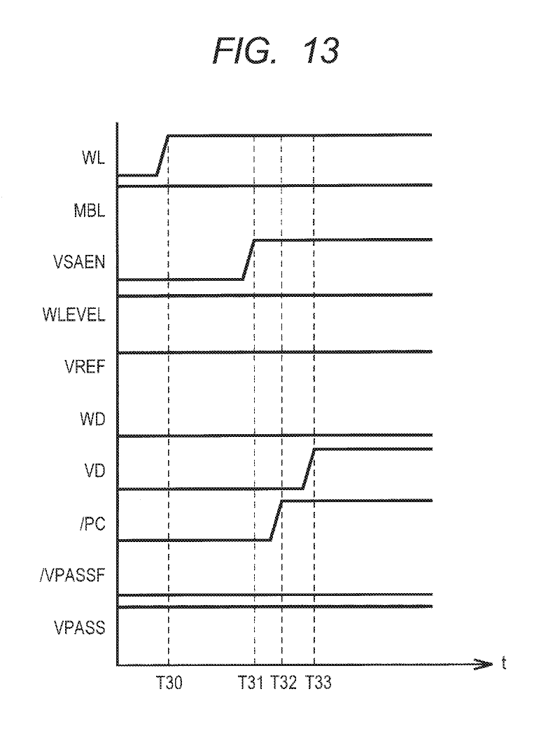

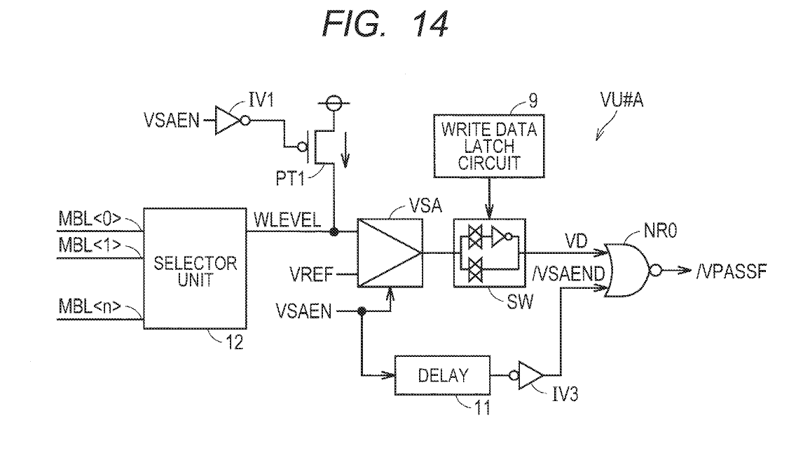

FIG. 13 is a diagram showing the operation waveform of the verify operation for data writing of data “0” based on the second embodiment.

As shown in FIG. 13, at time T30, the word line WL is selected and the memory cell MC and the bit line BL are coupled to each other. Further, the bit line BL and the data line are electrically coupled to each other according to the selector unit 12. Further, at time T30, the activation signal /PC is set to “L” level. In this way, the node N0 is charged to the power supply voltage VDD.

Next, at time 31, the control signal VSAEN is set to “H” level. In accordance with this, the transistor PT1 is conductive, and the data line is charged to the power supply voltage.

Further, because the data writing is performed on data “0”, the write data WD is set to “L” level. Thus, the transistor PT4 is in a conductive state. In this way, the data line is coupled to the power supply voltage VDD and is set to “H” level.

For this reason, the level of the bit line BL and the level of the data line are kept high regardless of the threshold voltage Vth of the memory cell MC.

The verify sense amplifier VSA is activated in response to the control signal VSAEN, and outputs verify data VD of “H” level.

Then, at time T32, the activation signal /PC is set to “H” level. In accordance with this, the determination circuit 7 is activated. The charging of the node N0 to the power supply voltage VDD is completed.

On the other hand, the verify data VD is “H” level, so that the signal /VPASSF is set to “L” level at time T33. Thus, the transistor NT3 of the determination circuit 7 is non conductive and the determination signal VPASS is set to “H” level.

Therefore, based on this result, it is possible to determine that the writing is normally performed. In other words, when the data writing is performed on data “0”, the verify sense amplifier VSA goes into an active state but the verify data VD is fixed at “H” level. Then, the signal /VPASSF is fixed at “L” level.

The method based on the second embodiment makes the verify process invalid by fixing the output of the verify sense amplifier VSA according to the data level of the write data WD.

When compared to the method of the first embodiment, the circuit configuration of the second embodiment is simple and can reduce the cost.

### Third Embodiment

FIG. 14 is a diagram showing the configuration of a verify unit VU#A based on a third embodiment.

As shown in FIG. 14, the verify unit VU#A includes the verify sense amplifier VSA, the transistor PT1, the inverters IV1 and IV3, the delay 11, the NOR circuit NR0, and a switch circuit SW. The transistor PT1 is a P channel MOS transistor as an example.

The transistor PT1 is provided between the data line and the power supply voltage VDD. The gate of the transistor PT1 receives an input of control signal VSAEN through the inverter IV1. The transistor PT1 is conductive in response to the input of control signal VSAEN (“H” level). In accordance with this, the data line is charged to the power supply voltage VDD.

The selector 12 selects the bit line BL. Then, the selected bit line BL is electrically couple to the data line.

In accordance with this, the current corresponding to the data of the memory cell MC flows through the bit line BL.

When the data is “1”, the threshold voltage of the memory cell MC is set to a high state, so that the voltage WLEVEL of the data line is higher than the reference voltage VREF.

On the other hand, when the data is “0”, the threshold voltage of the memory cell MC is set to a low state, so that the voltage WLEVEL of the data line is lower than the reference voltage VREF.

The verify sense amplifier VSA is activated in response to an activation signal.

The verify sense amplifier VSA compares the voltage of the data line with the reference voltage VREF, and outputs verify data VD. When the voltage WLEVEL of the data line is greater than the reference voltage VREF, the verify sense amplifier VSA outputs verify data VD (“H” level).

When the voltage WLEVEL of the data line is smaller than the reference voltage VREF, the verify sense amplifier VSA outputs verify data VD (“L” level).

The delay 11 delays the control signal VSAEN by a predetermined time. The inverter IV3 outputs signal VSAEND, which is obtained by inverting the signal output from the delay 11, to the NOR circuit NR0.

The NOR circuit NR0 outputs the result of the NOR operation between the verify data VD, which is output from the verify sense amplifier VSA, and the signal /VSAEND as signal /VPASSF.

The switch circuit SW is provided between the verify sense amplifier VSA and the NOR circuit NR0. The switch circuit SW has two system paths (upper and lower paths as an example) to switch the paths according to the word data WD from the write data latch circuit 9.

When the upper path is selected, the switch circuit SW inverts the verify data VD and outputs the inverted verify data. When the lower path is selected, the switch circuit SW just outputs the verify data VD. In the present embodiment, the upper path is selected when the write data WD is “0”, and the lower path is selected when the write data WD is “1”.

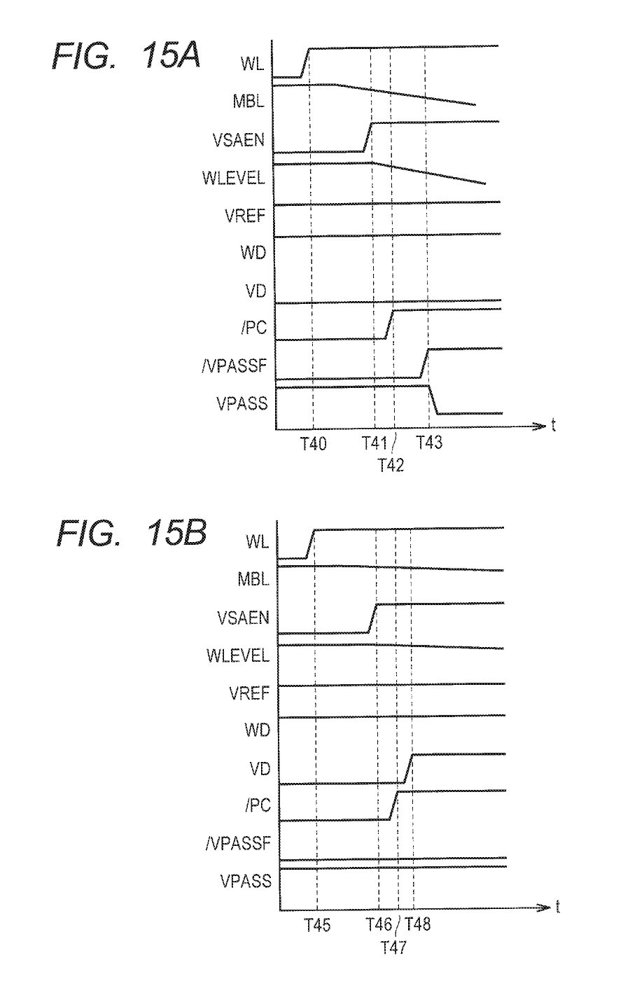

FIGS. 15A and 15B are diagrams showing the operation waveform of the verify operation when the data is written to the memory cell MC based on the third embodiment.

FIG. 15A shows the operation waveform when the data writing of data “1” is not completed.

At time T40, the word line WL is selected, and the memory cell MC and the bit line BL are coupled to each other. At the same time, the bit line BL and the data line are electrically coupled to each other according to the selector unit 12. Further, at time T40, the activation signal /PC is set to “L” level. Thus, the node N0 is charged to the power supply voltage VDD.

Next, at time T41, the control signal VSAEN is set to “H” level. In accordance with this, the transistor PT1 is conductive and the data line is charged to the power supply voltage.

On the other hand, the threshold voltage Vth of the memory cell MC is in a low state, so that the current flows through the memory cell MC. Thus, the potential of the bit line BL is reduced. At the same time, the level of the data line coupled to the bit line BL is also reduced.

Because the data writing is performed on data “1”, the write data WD is kept at “H” level. Thus, the switch circuit SW is in selecting the lower path.

The verify sense amplifier VSA is activated in response to the control signal VSAEN, and outputs verify data VD of “L” level.

Then, at time T42, the activation signal /PC is set to “H” level. In accordance with this, the determination circuit 7 is activated. The charging of the node N to the power supply voltage VDD is completed.

On the other hand, the verify data VD is “L” level, so that the signal /VPASSF is set to “H” level at time T43. For this reason, the transistor NT3 of the determination circuit 7 is conductive and the determination signal VPASS is set to “L” level.

Based on this result, rewriting is performed.

Next, FIG. 15B shows the operation waveform when the data writing of data “1” is completed.

At time T45, the word lien WL is selected and the memory cell MC and the bit line BL are coupled to each other. At the same time, the bit line BL and the data line are electrically coupled to each other according to the selector unit 12. Further, at time T45, the activation signal /PC is set to “L” level. Thus, the node N0 is charged to the power supply voltage VDD.

Next, at time T46, the control signal VSAEN is set to “H” level. In accordance with this, the transistor PT1 is conductive and the data line is charged to the power supply voltage.

On the other hand, the threshold voltage Vth of the memory cell MC is in a high state, so that the current is not likely to flow through the memory cell MC. For this reason, the potential of the bit line BL is kept high. Further, the level of the data line coupled to the bit line BL is also kept high.

Because the data writing is performed on data “1”, the write data WD is kept at “H” level. For this reason, the switch circuit SW is in selecting the lower path.

The verify sense amplifier VSA is activated in response to the control signal VSAEN, and outputs verify data VD of “H” level.

Then, at time T47, the activation signal /PC is set to “H” level. In accordance with this, the determination circuit 7 is activated. The charging of the node N0 to the power supply voltage VDD is completed.

On the other hand, the verify data VD is “H” level, so that the signal /VPASSF is set to “L” level at time T48. For this reason, the transistor NT3 of the determination circuit 7 is non conductive and the determination signal VPASS is set to “H” level.

Based on this result, it is possible to determine that the writing is normally performed.

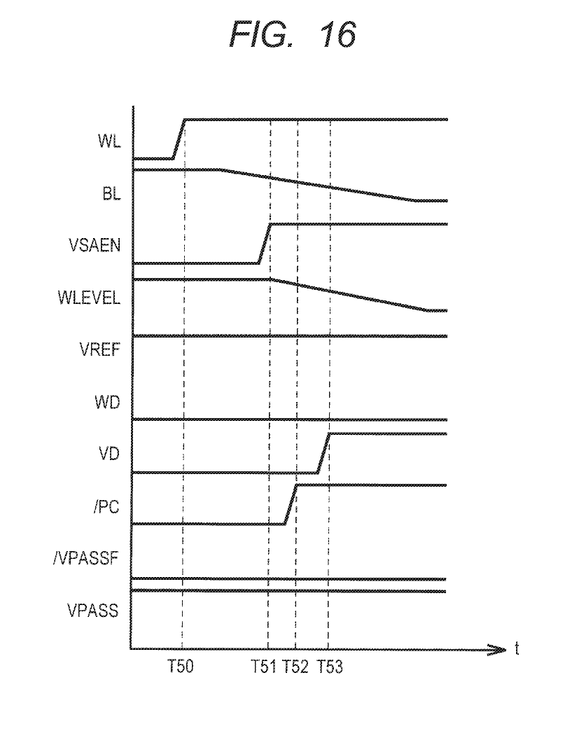

FIG. 16 is a diagram showing the operation waveform of the verify operation for data writing of data “0” based on the third embodiment.

As shown in FIG. 16, at time T50, the word line WL is selected, and the memory cell MC and the bit line BL are coupled to each other. At the same time, the bit line BL and the data line are electrically couple to each other according to the selector unit 12. Further, at time T50, the activation signal /PC is set to “L” level. Thus, the node N0 is charged to the power supply voltage VDD.

Next, at time 51, the control signal VSAEN is set to “H” level. In accordance with this, the transistor PT1 is conductive, and the data line is charged to the power supply voltage.

Further, because the data writing is performed on data “0”, the write data WD is set to “L” level. Thus, the switch circuit SW is in selecting the upper path.

On the other hand, the threshold voltage Vth of the memory cell MC is in a low state, so that the current flows through the memory cell MC. For this reason, the potential of the bit line BL is reduced. Further, the level of the data line coupled to the bit line BL is also reduced.

Because the data wiring of data “1” is performed, the write data WD is kept at “H” level. Thus, the switch circuit SW is in selecting the upper path.

The verify sense amplifier VSA is activated in response to the control signal VSEN, and outputs verify data VD of “L” level. On the other hand, the switch circuit SW selects the upper path, so that the verify data VD is inverted and is set to “H” level.

Then, at time T52, the activation signal /PC is set to “H” level. In accordance with this, the determination circuit 7 is activated. The charging of the node N0 to the power supply voltage VDD is completed.

On the other hand, the signal /VPASSE is set to “L” level at time T53 because the verify data VD is “H” level. For this reason, the transistor NT3 of the determination circuit 7 is non conductive and the determination signal VPASS is set to “H” level.

Therefore, based on this result, it is possible to determine that the writing is normally performed. In other words, when the data wiring of data “0” is performed, the verify sense amplifier VSA is put into an active state but the verify data VD is fixed at “H” level. Then, the signal /VPASSF is fixed at “L” level.

The method based on the third embodiment makes the verify process invalid by fixing the output of the verify sense amplifier VAS according to the data level of the write data WD.

When compared to the method of the first embodiment, the circuit configuration is simple and can reduce the cost.

Although the foregoing disclosure has been described in detail with reference to exemplary embodiments, it should be understood that this disclosure is not limited to the illustrative embodiments set forth herein, and various modifications can be made without departing from the scope and spirit of this disclosure.

What is claimed is:

1. A semiconductor device comprising:
memory cells arranged in a matrix form; and
a verify circuit that performs a verify operation to verify whether or not data is written to a memory cell,
wherein the verify circuit performs the verify operation when write data is in a first state, and
wherein the verify circuit does not perform the verify operation when the write data is in a second state.

2. The semiconductor device according to claim 1,
wherein when the write data is in the first state, the threshold voltage of the memory cell is set to a high state, and
wherein when the write data is in the second state, the threshold voltage of the memory cell is set to a low state.

3. The semiconductor device according to claim 1,
wherein the verify circuit comprises:
a comparison circuit that compares a voltage, which is in accordance with the data read from the memory cell, with a reference voltage; and
a determination circuit that determines whether or not the data writing is performed, based on the comparison result of the comparison circuit,
wherein when the write data is in the first state, the comparative circuit is activated, and
wherein when the write data is in the second state, the comparative circuit is not activated.

4. The semiconductor device according to claim 1, further comprising:
a plurality of bit lines provided corresponding to each of the memory cell columns; and
a setting circuit that sets a corresponding one of the bit lines to a predetermined voltage, according to write data,
wherein the verify circuit includes:
a comparison circuit that compares the voltage of a selected one of the bit lines with a reference voltage; and
a determination circuit that determines whether or not the data writing is performed based on the comparison result of the comparison circuit.

5. The semiconductor device according to claim 4,
wherein when the write data is in the second state, the selected bit line is set to the predetermined voltage, and
wherein the comparison circuit compares the predetermined voltage with the reference voltage, and outputs a fixed value based on the comparison result.

6. The semiconductor device according to claim 1, further comprising a plurality of bit lines provided corresponding to each of the memory cell columns,
wherein the verify circuit includes:
a comparison circuit that compares the voltage of a selected one of the bit lines with a reference voltage;
a setting circuit that, when the write data is in the second state, sets the comparison result of the comparison circuit to a fixed value; and
a determination circuit that determines whether or not the data writing is performed, based on the comparison result of the comparison circuit.
